(19) United States
(12) Patent Application Publication
(10) Pub. No.: US 2025/0215276 A1
(43) Pub. Date: Jul. 3, 2025

(54) ADHESIVE SHEET AND METHOD FOR MANUFACTURING ELECTRONIC COMPONENT OR SEMICONDUCTOR DEVICE

(71) Applicant: LINTEC Corporation, Tokyo (JP)

(72) Inventors: Kenta NISHIJIMA, Tokyo (JP); Go ONISHI, Tokyo (JP); Takashi SUGINO, Tokyo (JP)

(21) Appl. No.: 19/085,287

(22) Filed: Mar. 20, 2025

Related U.S. Application Data
(63) Continuation of application No. PCT/JP2023/034244, filed on Sep. 21, 2023.

(30) Foreign Application Priority Data
Sep. 22, 2022 (JP) 2022-151756
Sep. 22, 2022 (JP) 2022-151757

(51) Int. Cl. C09J 7/38; C09J 7/10; H01L 21/683

(52) U.S. Cl. CPC C09J 7/38; C09J 7/10; C09J 2203/326; C09J 2301/20; C09J 2301/302; H01L 21/6835

(57) ABSTRACT

Provided is a new method by which it is easier to remove an element after processing, so as to improve productivity in manufacturing an electronic component or a semiconductor device. An object to be processed used in manufacturing an electronic component or a semiconductor device is attached to an uneven surface of a pressure sensitive adhesive layer. The object to be processed on the pressure sensitive adhesive layer is processed to obtain a processed product. The processed product is removed from the pressure sensitive adhesive layer.

### CROSS-REFERENCE TO RELATED APPLICATIONS

This application is a Continuation of International Patent Application No. PCT/JP2023/034244, filed Sep. 21, 2023, which claims the benefit of Japanese Patent Application No. 2022-151756 filed on Sep. 22, 2022 and Japanese Patent Application No. 2022-151757 filed on Sep. 22, 2022, all of which are hereby incorporated by reference herein in their entirety.

### BACKGROUND

### Field

The present disclosure relates to a pressure sensitive adhesive sheet, and a method for manufacturing an electronic component or a semiconductor device, and for example, relates to a pressure sensitive adhesive sheet for capturing a semiconductor when a semiconductor element is transferred by a laser lift-off method.

### Description of the Related Art

An element used for an electronic component or a semiconductor device is often obtained by forming a large number of a plurality of elements at a time. For example, a semiconductor chip is obtained by dicing a semiconductor wafer adhering to a pressure sensitive adhesive. When such an element is mounted on the semiconductor device, the element is often transferred. In particular, in order to transfer the element to a desired position, it is required to selectively transfer a specific element from a pre-transfer substrate to a post-transfer substrate in a state where the pre-transfer substrate and the post-transfer substrate are detached from each other. For example, Japanese Patent Laid-Open No. 2021-141181 A discloses a method for transferring a semiconductor chip by irradiating the semiconductor chip with a laser (laser lift-off method).

### SUMMARY

According to an embodiment of the present invention, a pressure sensitive adhesive sheet for capturing an element detached from a holding substrate, the pressure sensitive adhesive sheet including a pressure sensitive adhesive layer having a surface having an unevenness.

Further features of the present invention will become apparent from the following description of exemplary embodiments with reference to the attached drawings.

### BRIEF DESCRIPTION OF THE DRAWINGS

The accompanying drawings, which are incorporated herein and constitute a part of the specification, illustrate embodiments of the present invention, and, together with the description, serve to describe the principles of the present invention.

FIG. 1 is a schematic view of a pressure sensitive adhesive sheet according to one embodiment.

FIG. 2A is a top view illustrating an example of an unevenness of a pressure sensitive adhesive layer.

FIG. 2B is a top view illustrating an example of an unevenness of a pressure sensitive adhesive layer.

FIG. 2C is a top view illustrating an example of an unevenness of a pressure sensitive adhesive layer.

FIG. 3A is a cross-sectional view illustrating an example of an unevenness of a pressure sensitive adhesive layer.

FIG. 3B is a cross-sectional view illustrating an example of an unevenness of a pressure sensitive adhesive layer.

FIG. 3C is a cross-sectional view illustrating an example of an unevenness of a pressure sensitive adhesive layer.

FIG. 4A is a diagram illustrating separation and capture of an element.

FIG. 4B is a diagram illustrating separation and capture of an element.

FIG. 5 is a flowchart of a method for manufacturing an electronic component or a semiconductor device according to one embodiment.

### DESCRIPTION OF THE EMBODIMENTS

An embodiment will be described below in detail with reference to the drawings. It should be noted that the following embodiments do not limit the invention according to the appended claims, and all combinations of features described in the embodiments are not necessarily essential to the invention. Any two or more features among a plurality of features described in the embodiments may be combined. The same or similar components are denoted by the same reference numerals, and redundant description is omitted.

When the element moves from the pre-transfer substrate to the post-transfer substrate, the element contacts the post-transfer substrate, and thus, the element is captured by the post-transfer substrate. If the element is transferred between parallel substrates, when the element moves in a direction perpendicular to a plane direction of both substrates, a position of the element on the pre-transfer substrate and a position of the element on the post-transfer substrate match with each other in a plan view of both substrates. However, it is found that when such an element is transferred, a shift tends to occur between the position of the element on the pre-transfer substrate and the position of the element on the post-transfer substrate. In recent years, the semiconductor device and the element are microfabricated, and such a shift in the transfer position may prevent further microfabrication.

As a result of intensive studies, the present inventors have found that if an unevenness is provided on a surface of a pressure sensitive adhesive sheet for capturing an element to be transferred, it is possible to suppress a shift of the element at the time of capturing, and thus, it is possible to solve the above-mentioned problem, and have further conducted various studies to complete the present invention.

To improve a positioning accuracy of a transfer position when an element is transferred.

Other features and advantages of the present invention will become apparent from the following description in conjunction with the accompanying drawings. Note that in the drawings, the same or similar components are denoted by the same reference numerals.

### Definitions

As used herein, a mass average molecular weight (Mw) and a number average molecular weight (Mn) are values measured by size exclusion chromatography and calibrated with a polystyrene standard, and more specifically, are values measured based on JIS K7252-1:2016. In addition, in the present specification, “(meth)acrylic” refers to both “acrylic” and “methacrylic”.

As used herein, the “electronic component” includes all components used in electronic engineering, electrical engineering, and the like, and all components included in an electronic device. The “electronic component” may be formed of any one of a semiconductor, a conductor, and/or an insulant, or a combination thereof. Examples of the “electronic components” include an active component (mainly formed of a semiconductor, for example, a transistor, an IC, an LSI, a super LSI, a diode, a light-emitting diode, a thyristor, a three terminal regulator, and an imaging device), a passive element (for example, a resistor, a capacitor, a speaker, a coil, an electric transformer, a transformer, a relay, a piezoelectric element, a quartz oscillator, a ceramic oscillator, and a varistor), and a structural component (for example, a wiring component, a printed circuit board, a connector, and a switch). Also as used herein, a “semiconductor device” refers to any general device that can function by utilizing a semiconductor characteristic and is used for a processor, a memory, a sensor, and the like. Examples of the “semiconductor device” include a micro-light-emitting diode, a mini-light-emitting diode, a power device, micro electro mechanical systems (MEMS), and a controller chip.

As used herein, when one or more lower limit values and one or more upper limit values of a numerical range (for example, a range of a content) are described, it can be understood that a combination of any one of the lower limit values and any one of the upper limit values is described. For example, the description “preferably 1 or greater, more preferably 2 or greater, and even more preferably 3 or greater, and preferably 9 or less, more preferably 8 or less, and even more preferably 7 or less” clearly means that the numerical range may be any of 1 or greater and 9 or less, 1 or greater and 8 or less, 1 or greater and 7 or less, 2 or greater and 9 or less, 2 or greater and 8 or less, 2 or greater and 7 or less, 3 or greater and 9 or less, 3 or greater and 8 or less, and 3 or greater and 7 or less.

### Configuration of Pressure Sensitive Adhesive Sheet

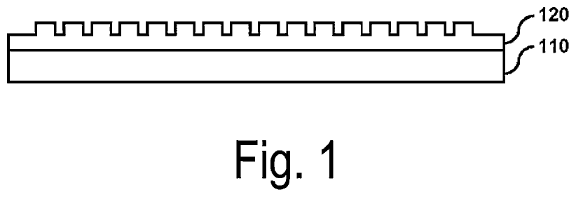

A pressure sensitive adhesive sheet according to one embodiment of the present invention includes a pressure sensitive adhesive layer 120 including an uneven surface. For example, the pressure sensitive adhesive sheet may include a base material 110 and the pressure sensitive adhesive layer 120. A configuration of such a pressure sensitive adhesive sheet will be described below with reference to FIG. 1 which is a schematic view of a pressure sensitive adhesive sheet according to one embodiment. However, it is not essential that the pressure sensitive adhesive sheet includes the base material 110. For example, the pressure sensitive adhesive sheet may include only the pressure sensitive adhesive layer 120. In such a case, the pressure sensitive adhesive sheet may employ the pressure sensitive adhesive layer 120 having a high supporting property.

### Base Material

The base material 110 included in the pressure sensitive adhesive sheet functions as a support supporting the pressure sensitive adhesive layer 120. A type of the base material 110 is not particularly limited, and may be a rigid base material or a flexible base material. The base material 110 is preferably a flexible base material from the viewpoint of improving a cushioning property in capturing an element, facilitating attachment to another member, improving a peeling property, facilitating lamination, or enabling a roll form. An example of the base material 110 includes a resin film.

The resin film is a film in which a resin-based material is used as a main material, and may be formed of a resin material or may contain an additive in addition to the resin material. The resin film may be permeable to laser light.

Specific examples of the resin film include a polyethylene film such as a low-density polyethylene (LDPE) film, a linear low-density polyethylene (LLDPE) film, and a high-density polyethylene (HDPE) film, a polyolefin-based film such as a polypropylene film, a polybutene film, a polybutadiene film, a polymethylpentene film, an ethylene-norbornene copolymer film, and a norbornene resin film; an ethylene-based copolymer film such as an ethylene-vinyl acetate copolymer film, an ethylene-(meth)acrylic acid copolymer film, and an ethylene-(meth)acrylic acid ester copolymer film; a polyvinyl chloride-based film such as a polyvinyl chloride film and a vinyl chloride copolymer film; a polyester-based film such as a polyethylene terephthalate film and a polybutylene terephthalate film; a polyurethane film; a polyimide film; a polystyrene film; a polycarbonate film; and a fluororesin film. In a film containing a mixture of two or more kinds of materials, a cross-linked film in which resins forming such films are cross-linked, and a modified film such as an ionomer film may be used. The base material 110 may be a laminated film in which two or more types of resin films are laminated.

From the viewpoint of versatility, relatively high strength and ease of preventing warpage, and a heat resistance, the resin film is preferably a single-layer film selected from the group consisting of a polyethylene film, a polyester-based film, and a polypropylene film, or a laminated film in which two or more films selected from such a group are laminated.

A thickness of the base material 110 is not particularly limited, but, from the viewpoint of satisfying both a supporting property and a roll winding property, is in a range of preferably from 10 μm to 500 μm, more preferably from 25 μm to 200 μm, and even more preferably from 40 μm to 90 μm.

### Pressure Sensitive Adhesive Layer

The pressure sensitive adhesive layer 120 is a layer having pressure sensitive adhesiveness and may include a resin. As described above, a surface of the pressure sensitive adhesive layer 120 has an unevenness. Note that the pressure sensitive adhesive sheet may include the pressure sensitive adhesive layer 120 having two or more layers. For example, the pressure sensitive adhesive sheet may have a laminate of one type or two or more types of pressure sensitive adhesive layers 120.

### Composition of Pressure Sensitive Adhesive Layer

Examples of resin contained in the pressure sensitive adhesive layer 120 include rubber-based resins such as polyisobutylene-based resins, polybutadiene-based resins, and styrene-butadiene-based resins; acrylic-based resins; urethane-based resins; polyester-based resins; olefin-based resins; silicone-based resins; and polyvinyl ether-based resins. The pressure sensitive adhesive layer may have a heat resistance, and examples of a material of the pressure sensitive adhesive layer having such a heat resistance include a polyimide-based resin and a silicone-based resin. The pressure sensitive adhesive layer 120 may include a copolymer having two or more kinds of constituent units. A form of such a copolymer is not particularly limited, and the copolymer may be any of a block copolymer, a random copolymer, an alternating copolymer, or a graft copolymer.

The resin included in the pressure sensitive adhesive layer 120 is preferably a pressure sensitive adhesive resin having a pressure sensitive adhesiveness on its own. The resin is preferably a polymer having a mass average molecular weight (Mw) of 10,000 or greater. From the viewpoint of improving the adhesion, the mass average molecular weight (Mw) of the resin is preferably 10,000 or greater, more preferably from 70,000 or greater, and even more preferably from 140,000. From a viewpoint of suppressing a storage modulus to a predetermined value or less, the mass average molecular weight (Mw) of the resin is preferably 2,000,000 or less, more preferably 1,200,000 or less, and even more preferably 900,000 or less. From the viewpoint of improving the adhesion, the number average molecular weight (Mw) of the resin is preferably 10,000 or greater, more preferably 50,000 or greater, and even more preferably 100,000 or greater. From the viewpoint of suppressing the storage modulus to a predetermined value or less, the number average molecular weight (Mw) of the resin is preferably 2,000,000 or less, more preferably 1,000,000 or less, and even more preferably 700,000 or less. As will be described later, if the pressure sensitive adhesive layer 120 includes a resin derived from an energy-reactive resin, the mass average molecular weight (Mw) and the number average molecular weight (Mn) refer to the mass average molecular weight (Mw) and the number average molecular weight (Mn) before a cross-linking reaction by energy application. A glass transition temperature (Tg) of the resin is preferably −70° C. or higher, and more preferably −60° C. or higher, and preferably −10° C. or lower, and more preferably −20° C. or lower. When the Tg is within the above range, it is possible to easily maintain the adhesion and the storage modulus of the obtained pressure sensitive adhesive within ranges described later.

An amount of the resin included in the pressure sensitive adhesive layer 120 relative to the total amount of the components included in the pressure sensitive adhesive layer 120 may be appropriately set according to a required adhesion and storage modulus of the pressure sensitive adhesive layer 120, and is preferably 30 mass % or greater, more preferably 40 mass % or greater, even more preferably 50 mass % or greater, still more preferably 55 mass % or greater, and still even more preferably 60 mass % or greater, and preferably 99.99 mass % or less, more preferably 99.95 mass % or less, even more preferably 99.90 mass % or less, still more preferably 99.80 mass % or less, and still even more preferably 99.50 mass % or less.

From the viewpoint of a morphological stability of the uneven shape of the surface of the pressure sensitive adhesive layer, the storage modulus of the pressure sensitive adhesive layer 120 is preferably 0.001 MPa or greater, more preferably 0.01 MPa or greater, even more preferably 0.03 MPa or greater, and still more preferably 0.07 MPa or greater. On the other hand, it is preferable that the storage modulus of the pressure sensitive adhesive layer 120 be low in terms of being able to suppress a positional deviation when the element is captured. From such a viewpoint, the storage modulus of the pressure sensitive adhesive layer 120 is preferably 100 MPa or less, more preferably 10 MPa or less, even more preferably 5 MPa or less, still more preferably 2 MPa or less, still even more preferably 1 MPa or less, further more preferably 0.5 MPa or less, even further more preferably 0.3 MPa or less, still further more preferably 0.25 MPa or less, and even still further more preferably 0.2 MPa or less. In the present specification, the storage modulus is measured in accordance with JIS K7244-1: 1998. Specifically, the storage modulus of the pressure sensitive adhesive layer 120 can be measured as follows. A cylindrical sample having a thickness of 3 mm and a diameter of 8 mm is prepared. The storage modulus of the sample is measured by a torsional shear method under conditions including 1 Hz and 23° C. using a viscoelasticity measuring device.

The adhesion of the pressure sensitive adhesive layer 120 is preferably 0.01 N/25 mm or greater, more preferably 0.1 N/25 mm or greater, even more preferably 0.2 N/25 mm or greater, still more preferably 0.3 N/25 mm or greater, and still even more preferably 0.4 N/25 mm or greater, so as to suppress a positional deviation in capturing an element, and is preferably 100 N/25 mm or less, more preferably 10 N/25 mm or less, and even more preferably 1 N/25 mm or less, so as not to damage the captured element when peeling the captured element from the pressure sensitive adhesive layer 120. In the present specification, the adhesion is measured in accordance with JIS Z0237: 2009.

The resin contained in the pressure sensitive adhesive layer 120 is preferably a thermoplastic resin. That is, the pressure sensitive adhesive layer 120 preferably has thermoplasticity. In the case of using a thermoplastic resin, it is easy to form an uneven shape on the pressure sensitive adhesive layer 120 by heating and softening the resin, and it is easy to maintain the formed uneven shape by cooling the resin. Examples of the thermoplastic resin include rubber-based resins, acrylic-based resins, urethane-based resins, and olefin-based resins. More preferable examples of the thermoplastic resin include a polybutadiene-based thermoplastic elastomer using butadiene as a monomer, a styrene-based thermoplastic elastomer (TPS) using styrene as a monomer, and an acrylic thermoplastic elastomer using (meth)acrylic acid ester as a monomer.

The resin contained in the pressure sensitive adhesive layer 120 is preferably derived from an energy-reactive resin. The energy-reactive resin refers to a resin having an improved elastic modulus when energy is applied. Examples of the energy-reactive resin include an energy ray-reactive resin and a heat-reactive resin. The energy ray-reactive resin refers to a resin having an improved elastic modulus when the resin is irradiated with energy rays. The heat-reactive resin refers to a resin having an improved elastic modulus when the resin is heated. The resin contained in the pressure sensitive adhesive layer 120 is more preferably derived from a thermoplastic energy-reactive resin, and even more preferably from a thermoplastic energy ray-reactive resin. The type of the energy rays is not particularly limited, and examples thereof include ultraviolet rays, electron beams, and ionizing radiation. The energy rays are preferably ultraviolet rays, that is, the resin is preferably an ultraviolet-reactive resin.

The thermoplastic energy-reactive resin refers to an energy-reactive resin having thermoplasticity at least before energy is applied. Furthermore, the fact that the resin is derived from an energy-reactive resin means that the resin is obtained from an energy-reactive resin. For example, the resin derived from an energy-reactive resin is a cross-linked energy-reactive resin.

In the case of using such an energy-reactive resin, when an uneven shape is formed on the resin, and then, energy is applied (for example, the resin is irradiated with energy rays), it is easy to maintain the formed uneven shape.

An example of such an energy-reactive resin includes a polymer into which a polymerizable functional group is introduced. The polymerizable functional group is a functional group cross-linked by application of energy (for example, irradiation with energy rays). Examples of the polymerizable functional group include an alkenyl group such as a vinyl group and an allyl group, a (meth)acryloyl group, an oxetanyl group, and an epoxy group.

An example of the energy-reactive resin includes a diene-based rubber formed of a polymer having a polymerizable functional group at a main chain terminal end and/or a side chain. The diene-based rubber refers to a rubber-like polymer having a double bond in a main chain of the polymer. A specific example of the diene-based rubber includes a polymer in which butadiene or isoprene is used as a monomer (that is, a polymer having a butenediyl group or a pentenediyl group as a constitutional unit). Preferable examples of the energy-reactive resin include a polybutadiene resin (PB resin), a styrene-butadiene-styrene block copolymer (SBS resin), and a styrene-isoprene-styrene block copolymer (SIS resin). Such resins can be used as the ultraviolet-reactive resin.

The average number of polymerizable functional groups per molecule in such energy-reactive resins is preferably 1.5 or greater, and more preferably 2 or greater, so that the uneven shape of the pressure sensitive adhesive layer is easily maintained. On the other hand, the average number is preferably 20 or less, more preferably 15 or less, and even more preferably 10 or less, so that the pressure sensitive adhesiveness and the flexibility of the pressure sensitive adhesive layer is increased.

The pressure sensitive adhesive layer 120 may contain one type of resin or may contain two or more types of resins. The pressure sensitive adhesive layer 120 according to one embodiment contains a liquid resin or a resin derived from an energy-reactive liquid resin, in addition to the resin derived from a thermoplastic resin or the thermoplastic energy-reactive resin. The liquid resin refers to a resin in a liquid state at ordinary temperature (25° C.) before mixing. The energy-reactive liquid resin refers to an energy-reactive resin in a liquid state at ordinary temperature (25° C.) before mixing and before applying energy. Thus, it is easy to control the adhesion and the storage modulus of the pressure sensitive adhesive layer 120 by adding the liquid resin.

The pressure sensitive adhesive layer 120 according to one embodiment preferably contains a resin derived from an energy-reactive liquid resin, because the uneven shape of the pressure sensitive adhesive layer is easily maintained. An example of such liquid resins include a diene-based rubber, and a specific example thereof includes polybutadiene resins in which butadiene is used as a monomer.

The pressure sensitive adhesive layer 120 according to one embodiment contains a combination of a resin derived from a thermoplastic energy-reactive resin and a resin derived from an energy-reactive liquid resin. Preferably, the pressure sensitive adhesive layer 120 contains a combination of a resin derived from an energy ray-reactive styrene-based thermoplastic elastomer and a resin derived from a diene-based rubber which is an energy ray-reactive liquid resin.

A preferable example of the thermoplastic energy ray-reactive resin includes a resin in which styrene and butadiene are used as monomers, and a particularly preferable example thereof includes an SBS resin. The resin in which styrene and butadiene are used as monomers includes not only a resin in which only styrene and butadiene are used as monomers, but also a resin in which a monomer other than styrene and butadiene is further used. From the viewpoint of improving the pressure sensitive adhesiveness of the pressure sensitive adhesive layer 120, the mass average molecular weight (Mw) of such a resin is preferably 10,000 or greater, more preferably 50,000 or greater, even more preferably 100,000 or greater, and still more preferably 150,000 or greater. The mass average molecular weight (Mw) of such a resin is preferably 2,000,000 or less, more preferably 1,000,000 or less, and even more preferably 200,000 or less, in order to reduce the storage modulus of the pressure sensitive adhesive layer 120 to an appropriate range. For the same reason, the number average molecular weight (Mn) of such a resin is preferably 10,000 or greater, more preferably 30,000 or greater, even more preferably 70,000 or greater, and still more preferably 130,000 or greater. On the other hand, the number average molecular weight is preferably 2,000,000 or less, more preferably 1,000,000 or less, and even more preferably 200,000 or less.

A preferable example of the energy ray-reactive liquid resin includes a resin in which butadiene is used as a monomer, and a particularly preferable example includes a PB resin. The resin in which butadiene is used as a monomer includes not only a resin in which only butadiene is used as a monomer, but also a resin in which a monomer other than butadiene is further used. The mass average molecular weight (Mw) of such a resin is preferably 500 or greater, more preferably 1,000 or greater, even more preferably 2000 or greater, and still more preferably 3,000 or greater, in order to increase the storage modulus of the pressure sensitive adhesive layer 120. Furthermore, the mass average molecular weight (Mw) of such a resin is preferably 500,000 or less, more preferably 100,000 or less, and even more preferably 10,000 or less, in order to decrease the storage modulus of the pressure sensitive adhesive layer 120. For the same reason, the number average molecular weight (Mn) of such a resin is preferably 500 or greater, more preferably 1,000 or greater, even more preferably 3,000 or greater, and still more preferably 120,000 or greater, and is preferably 500,000 or less, more preferably 100,000 or less, and even more preferably 10,000 or less.

The ratio of the resin derived from the thermoplastic energy-reactive resin and the resin derived from the energy-reactive liquid resin contained in the pressure sensitive adhesive layer 120 can be selected in accordance with the required adhesion, the storage modulus, and the like of the pressure sensitive adhesive layer 120. For example, the amount of the resin derived from the energy-reactive liquid resin with respect to 100 parts by mass of the amount of the resin derived from the thermoplastic energy-reactive resin may be 10 parts by mass or greater, 30 parts by mass or greater, or 40 parts by mass or greater, in order to increase the adhesion, and may be 500 parts by mass or less, 200 parts by mass or less, or 150 parts by mass or less, in order to increase the storage modulus.

The ratio of the total amount of the resin derived from the thermoplastic energy-reactive resin and the resin derived from the energy-reactive liquid resin with respect to the total amount of the components constituting the pressure sensitive adhesive layer 120 can be selected in accordance with the required adhesion, the storage modulus, and the like of the pressure sensitive adhesive layer 120. For example, the ratio is preferably 30 mass % or greater, more preferably 40 mass % or greater, even more preferably 50 mass % or greater, still more preferably 55 mass % or greater, and still even more preferably 60 mass % or greater, and preferably 99.99 mass % or less, more preferably 99.95 mass % or less, even more preferably 99.90 mass % or less, still more preferably 99.80mass % or less, and still even more preferably 99.50 mass % or less.

The pressure sensitive adhesive layer 120 may contain a component other than the resin. For example, the pressure sensitive adhesive layer 120 may include one or more among a tackifier, a polymerization initiator, a UV absorber, and other additives.

The polymerization initiator is a component that initiates a cross-linking reaction in response to application of energy (for example, irradiation with energy rays). In a case where the pressure sensitive adhesive layer 120 contains an energy-reactive resin, if the pressure sensitive adhesive layer 120 further contains a polymerization initiator, the cross-linking reaction proceeds even by application of relatively low energy.

An example of the polymerization initiator may include a photopolymerization initiator. Examples of the photopolymerization initiator include 1-hydroxycyclohexyl phenyl ketone, benzoin, benzoin methyl ether, benzoin ethyl ether, benzoin propyl ether, benzyl phenyl sulfide, tetramethylthiuram monosulfide, azobisisobutyronitrile, dibenzyl, diacetyl, and 8-chloroanthraquinone.

The pressure sensitive adhesive layer 120 may contain one type of polymerization initiator or may contain two or more types of polymerization initiators. When the pressure sensitive adhesive layer 120 contains a polymerization initiator, the content of the polymerization initiator in the pressure sensitive adhesive layer 120 is preferably 0.01 mass % or greater, more preferably 0.1 mass % or greater, and even more preferably 1 mass % or greater, and preferably 10 mass % or less, more preferably 5 mass % or less, and even more preferably 2 mass % or less, so that the cross-linking reaction proceeds at an appropriate rate.

Examples of the UV absorber include a benzotriazole-based compound, an oxazolic acid amide compound, and a benzophenone-based compound.

Other additives that may be contained in the pressure sensitive adhesive layer 120 are not particularly limited, and examples thereof include photostabilizers such as hindered amine-based photostabilizers, benzophenone-based photostabilizers, and benzotriazole-based photostabilizers, phenol-based antioxidants such as hindered phenol-based compounds, aromatic amine-based antioxidants, sulfur-based antioxidants, and phosphorus-based antioxidants such as phosphate-based compounds, resin stabilizers such as imidazole-based resin stabilizers, dithiocarbamate-based resin stabilizers, phosphorus-based resin stabilizers, and sulfur ester-based resin stabilizers, fillers, pigments, extenders, and softners.

When the pressure sensitive adhesive layer 120 contains such additives, the content of the additives in the pressure sensitive adhesive layer 120 is preferably 0.0001 mass % or greater, more preferably 0.01 mass % or greater, particularly preferably 0.1 mass % or greater, and even more preferably 1 mass % or greater, and preferably 20 mass % or less, more preferably 10 mass % or less, and even more preferably 5 mass % or less.

### Shape of Pressure Sensitive Adhesive Layer

The surface of the pressure sensitive adhesive layer 120 has an unevenness. As described below, the pressure sensitive adhesive sheet can capture, in the pressure sensitive adhesive layer 120, an element separated from the holding substrate. Specifically, the pressure sensitive adhesive sheet can capture the element at a convex portion of the pressure sensitive adhesive layer 120. On the other hand, gas compressed between the element and the pressure sensitive adhesive layer 120 when the element and the pressure sensitive adhesive layer 120 closely contact each other can escape to a concave portion of the pressure sensitive adhesive sheet. As described above, the pressure sensitive adhesive layer 120 has an unevenness, and thus, pressure generated between the element and the pressure sensitive adhesive layer 120 can be relaxed. Therefore, it is also possible to suppress a displacement of a holding position of the element on the pressure sensitive adhesive sheet due to the pressure generated between the element and the pressure sensitive adhesive layer 120.

As described above, when the surface of the pressure sensitive adhesive layer 120 includes the concave portion, the pressure generated between the element and the pressure sensitive adhesive layer 120 can be relaxed. Therefore, a specific shape of the unevenness of the surface of the pressure sensitive adhesive layer 120 is not limited.

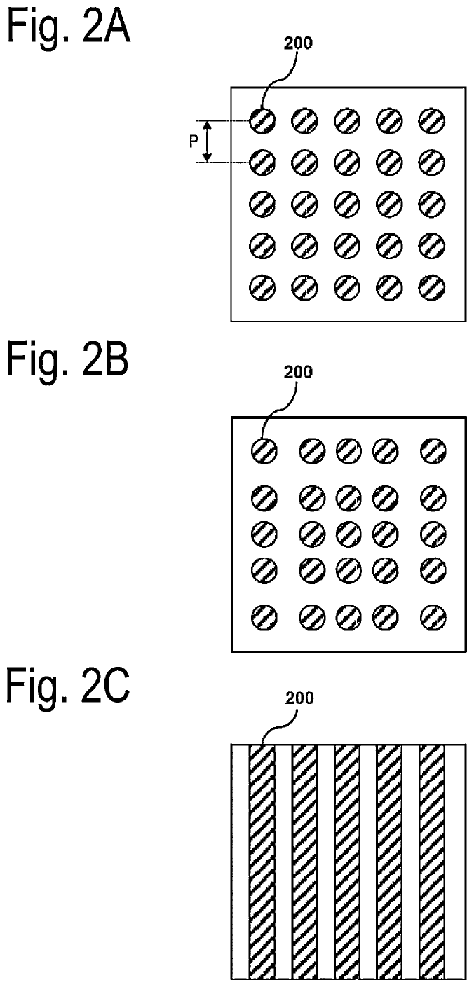

For example, in one embodiment, the pressure sensitive adhesive layer 120 includes, on a surface thereof, a plurality of convex portions separated from each other via a concave portion. Each of the plurality of convex portions may be separated by the concave portion continuing over the entire pressure sensitive adhesive layer 120. By providing the continuous concave portion in the periphery of the convex portions, it is possible to enhance an effect of relaxing pressure. In one embodiment, the concave portion positioned in the periphery of each of the plurality of convex portions is continuous to an end portion of the pressure sensitive adhesive layer 120. As described above, by providing the concave portion continuing to the end portion of the pressure sensitive adhesive layer 120, the air compressed between the element and the convex portions of the pressure sensitive adhesive layer 120 can be efficiently released to the outside of the element. FIGS. 2A to 2C are top views illustrating the shape of such a pressure sensitive adhesive layer 120.

As illustrated in FIG. 2A, the convex portions may be regularly arranged on the surface of the pressure sensitive adhesive layer 120. The regular arrangement of the convex portions refers to an arrangement in which the convex portions are arranged at regular intervals on a straight line. As illustrated in FIG. 2B, the convex portions may be arranged so that the intervals thereof vary regularly. In the example illustrated in FIG. 2B, the intervals between the convex portions are short in a central portion of the pressure sensitive adhesive sheet, and the intervals between the convex portions are long in a peripheral portion of the pressure sensitive adhesive sheet. According to such a configuration, it is possible to efficiently release the compressed air from the peripheral portion of the element via a wider concave portion, while increasing the holding power of the pressure sensitive adhesive sheet. Furthermore, the convex portions may be arranged irregularly.

FIG. 2C is a top view illustrating another shape of the pressure sensitive adhesive layer 120. As illustrated in FIG. 2C, stripe-shaped convex portions may be provided on the surface of the pressure sensitive adhesive layer 120. In FIG. 2C, line-shaped convex portions having constant widths are arranged at constant intervals. On the other hand, similarly to FIG. 2B, the widths or the intervals of the line-shaped convex portions may vary regularly, or the line-shaped convex portions may be arranged irregularly.

A pitch of the convex portions is preferably 1 μm or greater, more preferably 5 μm or greater, even more preferably 10 μm or greater, and still more preferably 15 μm or greater, in order to enhance an effect of relaxing pressure. On the other hand, the pitch is preferably 100 μm or less, more preferably 75 μm or less, even more preferably 50 μm or less, still more preferably 35 μm or less, and still even more preferably 25 μm or less, in order to increase a contact area between the pressure sensitive adhesive layer 120 and the element to suppress the positional deviation when capturing the element. Here, the pitch of the convex portions refers to a minimum interval among all intervals of the convex portions in the entire pressure sensitive adhesive layer 120. For example, in the case of FIG. 2A, the pitch of the convex portions represents an interval between the convex portions on a straight line on which the convex portions are arranged at constant intervals. When the convex portions are arranged on a plurality of straight lines, the pitch represents an interval between convex portions on a straight line on which the convex portions are arranged at the shortest intervals. In the case of FIG. 2C, the pitch of the convex portions represents an interval between the line-shaped convex portions. In the present specification, the interval between the convex portions refers to an interval between centers of the convex portions.

As illustrated in FIG. 2B, the shortest interval among all the intervals between the convex portions in the central portion of the pressure sensitive adhesive sheet may be shorter than the shortest interval among all the intervals between the convex portions in the peripheral portion of the pressure sensitive adhesive sheet. For example, the central portion is a circular region including 1/4 of the area of the pressure sensitive adhesive sheet and being centered on the center of gravity of the pressure sensitive adhesive sheet. The peripheral portion of the pressure sensitive adhesive sheet includes, for example, the entire region other than the central portion of the pressure sensitive adhesive sheet.

A specific shape of each of the convex portions is not particularly limited. For example, the convex portion may have a pillar (column) shape. In a specific example, the convex portion may have a cylindrical shape or a prismatic shape. The convex portion may extend in a line shape as described above, or may extend in a curved shape such as a wave shape. Furthermore, each of the convex portions may be tapered.

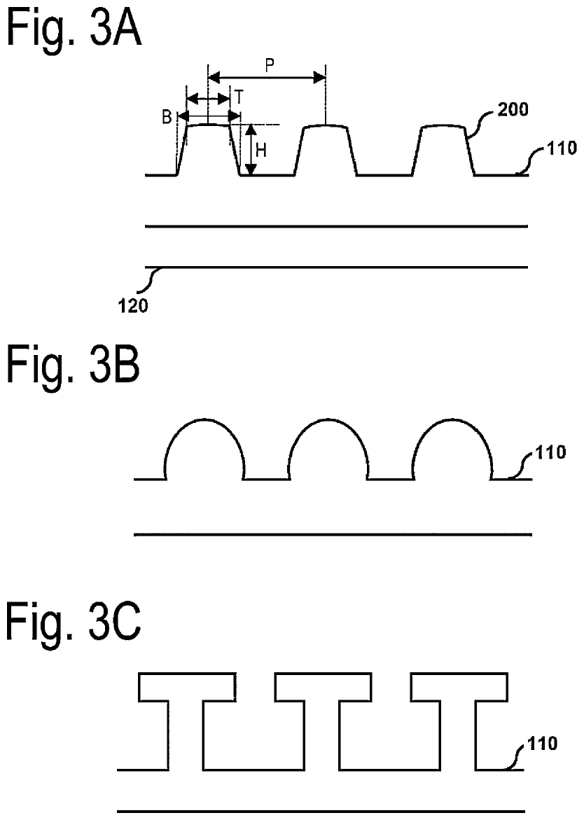

FIG. 3A illustrates a cross-sectional view of the pressure sensitive adhesive layer 120 according to one embodiment, and the cross-sectional view is cut through the convex portions and is perpendicular to the surface of the pressure sensitive adhesive layer 120. The convex portions illustrated in FIG. 3A are tapered, that is, the convex portions decrease in width toward the top. As illustrated in FIG. 3A, a top of each of the convex portions may be a curved surface. According to such a configuration, the impact when an element separated from the holding substrate and the pressure sensitive adhesive layer 120 contact each other is further relaxed. Therefore, the pressure sensitive adhesive layer 120 can easily hold the element without the element being displaced. The top of the convex portion may be a flat surface.

As illustrated in FIG. 3A, the surface of the pressure sensitive adhesive layer 120 may have a flat concave portion and convex portions protruding from the concave portion. As described above, the plurality of convex portions that are included in the pressure sensitive adhesive layer 120 and are separated from each other may be separated with a boundary defined by the concave portion.

In another example, each of the convex portions may have a hemispherical shape or may be a part of a sphere, as illustrated in FIG. 3B. The convex portion may have a T-shape, as illustrated in FIG. 3C. In still another example, the convex portion may have a shape in which a plurality of grains are gathered, a mushroom shape, a lotus leaf surface shape, or a needle shape. In still another example, the surface of the pressure sensitive adhesive layer 120 may be a rough surface or may be in the shape of fibers, and such a surface also has an unevenness.

The width or the diameter of each of the convex portions is preferably 1 μm or greater, more preferably 2 μm or greater, even more preferably 5 μm or greater, and still more preferably 10 μm or greater, in order to enhance the adhesiveness and suppress the positional deviation in capturing an element. On the other hand, the width or the diameter of each of the convex portions is preferably 100 μm or less, more preferably 50 μm or less, even more preferably 30 μm or less, and still more preferably 20 μm or less, in order to enhance the effect of relaxing pressure. Here, the width and the diameter of the convex portions respectively refer to the shortest distance and the longest distance (indicated by B in FIG. 3A) between two parallel lines contacting from both sides of the convex portions on the surface of the concave portion.

The area of each of the convex portions is preferably 10 μm² or greater, more preferably 20 μm² or greater, and even more preferably 30 μm² or greater, in order to enhance the adhesiveness and suppress the positional deviation in capturing an element. On the other hand, the area of each of the convex portions is preferably 2000 μm² or less, more preferably 1000 μm² or less, and even more preferably 500 μm² or less, in order to enhance the effect of relaxing pressure. Here, the area of the convex portion refers to an area of a portion protruding from the surface of the concave portion (an area of a circle having a diameter B in the case of FIG. 3A).

The height of each of the convex portions is preferably 1 μm or greater, more preferably 3 μm or greater, and even more preferably 5 μm or greater, in order to enhance an impact absorption property and suppress the positional deviation in capturing an element. On the other hand, the height of each of the convex portions is preferably 20 μm or less, more preferably 15 μm or less, and even more preferably 10 μm or less, in order to enhance the morphological stability. Here, the height of the convex portion is represented by H in FIG. 3A.

An area occupied by the plurality of convex portions relative to the area of the pressure sensitive adhesive layer 120 is preferably 1% or greater, more preferably 5% or greater, even more preferably 10% or greater, still more preferably 18% or greater, and still even more preferably 40% or greater, in order to enhance the adhesiveness and suppress the positional deviation in capturing an element. On the other hand, the area of each of the convex portions is preferably 95% or less, more preferably 75% or less, and even more preferably 60% or less, in order to enhance the effect of relaxing pressure.

The unevenness of the pressure sensitive adhesive layer 120 may be designed in accordance with the shape of the element to be captured by the pressure sensitive adhesive sheet. For example, the ratio of the adhesion area between the pressure sensitive adhesive layer 120 and one element relative to the area of one element is preferably 1% or greater, more preferably 2% or greater, even more preferably 3% or greater, still more preferably 4% or greater, still even more preferably 5% or greater, further more preferably 7% or greater, and even further more preferably 10% or greater, in order to enhance the adhesiveness and suppress the positional deviation in capturing an element. On the other hand, the area of each of the convex portions is preferably 95% or less, more preferably 70% or less, even more preferably 50% or less, and still more preferably 30% or less, in order to enhance the effect of relaxing pressure. In the case of FIG. 3A, the adhesion area corresponds to the area of a circle having a diameter T. When a position where the element is captured on the pressure sensitive adhesive sheet deviates, the adhesion area may change. In such a case, it is preferable that the ratio of the adhesion areas be within the above-mentioned range, regardless of a position where the element is captured.

### Other Layers

The pressure sensitive adhesive sheet may include a layer other than the base material 110 and the pressure sensitive adhesive layer 120. For example, an additional pressure sensitive adhesive layer may be provided on the surface of the base material 110 on the opposite side of the pressure sensitive adhesive layer 120. The pressure sensitive adhesive sheet may attach to another substrate such as quartz glass via such a pressure sensitive adhesive layer. The type of the additional pressure sensitive adhesive layer is not particularly limited, and for example, the additional pressure sensitive adhesive layer can be formed by using a general pressure sensitive adhesive.

### Method for Manufacturing Pressure Sensitive Adhesive Sheet

A method for manufacturing a pressure sensitive adhesive sheet is not particularly limited. For example, a pressure sensitive adhesive sheet including the pressure sensitive adhesive layer 120 on the base material 110 can be prepared as described below. First, an organic solvent is added to a raw material composition containing each component of the pressure sensitive adhesive layer 120 described above, to prepare a solution of the raw material composition. The solution can be applied onto a base material to form a coating film, and then the coating film is dried to provide the pressure sensitive adhesive layer on the base material 110. Furthermore, processing can be performed to provide an unevenness on the surface of the pressure sensitive adhesive layer, and thus, the pressure sensitive adhesive layer 120 having an unevenness can be formed.

Examples of the organic solvent used for preparing the solution of the raw material composition include toluene, ethyl acetate, and methyl ethyl ketone. The solid content concentration of the solution of the raw material composition is preferably 10 mass % or greater, more preferably 25 mass % or greater, and even more preferably 45 mass % or greater, and is preferably 80 mass % or less, more preferably 70 mass % or less, and even more preferably 65 mass % or less. Examples of a coating method of the solution include a spin coating method, a spray coating method, a bar coating method, a knife coating method, a roll coating method, a roll knife coating method, a blade coating method, a die coating method, a gravure coating method, and a printing method (for example, a screen printing method and an ink jet method).

The processing for providing an unevenness on the surface of the pressure sensitive adhesive layer is also not particularly limited. For example, an imprint method can be used to provide an unevenness on the surface of the pressure sensitive adhesive layer. In the imprint method, it is possible to use a mold having a surface of which the shape is complementary to the unevenness to be provided. Specifically, the unevenness can be provided on the surface of the pressure sensitive adhesive layer by heating the pressure sensitive adhesive layer provided on the base material while pressing the pressure sensitive adhesive layer with a mold. A more specific example of the method includes a method in which the pressure sensitive adhesive layer is pressed with a mold, and the pressure sensitive adhesive layer is heated and maintained in the heated state for a predetermined time. Subsequently, the pressure sensitive adhesive layer is cooled, and the mold can be removed. When the pressure sensitive adhesive layer is heated, for example, the pressure sensitive adhesive layer can be heated to a temperature higher than the softening point of the pressure sensitive adhesive layer. The time during which the pressure sensitive adhesive layer is maintained in the heated state is not particularly limited. For example, the pressure sensitive adhesive layer may be maintained in the heated state during 10 seconds or more, or during 10 minutes or less. A specific example of a method for heating the pressure sensitive adhesive layer while pressing the pressure sensitive adhesive layer with the mold, includes a method for vacuum laminating the mold and the pressure sensitive adhesive layer provided on the base material. Instead of performing a two-step process of forming the pressure sensitive adhesive layer and forming the unevenness, the pressure sensitive adhesive layer 120 having an unevenness on the surface may be formed on the base material in a one-step process.

In another method, the pressure sensitive adhesive layer 120 having an uneven shape can be provided by applying a solution of the raw material composition as a spray. Furthermore, the pressure sensitive adhesive layer 120 having a rough surface or a surface in the shape of fibers can be provided by adding a filler to the solution of the raw material composition and applying the obtained solution. In still another method, a solution of the raw material composition is applied according to a desired pattern by using a printing method such as an ink jet method, and thus, it is possible to directly provide the pressure sensitive adhesive layer having an uneven shape on the base material.

A pressure sensitive adhesive sheet in which the base material 110 is not provided can be manufactured by forming a sheet of a composition containing each component of the pressure sensitive adhesive layer. Furthermore, a liquid pressure sensitive adhesive containing each component of the pressure sensitive adhesive layer may be applied onto any object to form the pressure sensitive adhesive layer. In such a cases, after the pressure sensitive adhesive layer is formed, the surface of the pressure sensitive adhesive layer may be subjected to processing for providing an unevenness. Alternatively, the pressure sensitive adhesive layer may be formed by a method for forming an unevenness on a surface.

### Method for Manufacturing Electronic Component or Semiconductor Device Using Pressure Sensitive Adhesive Sheet

The above-described pressure sensitive adhesive sheet according to one embodiment of the present invention can be used for capturing an element detached from a holding substrate. For example, the pressure sensitive adhesive sheet can be used as a die catch sheet for catching a die such as a semiconductor die. The element is used for manufacturing an electronic component or a semiconductor device. That is, such a pressure sensitive adhesive sheet can be suitably used in manufacturing an electronic component or a semiconductor device.

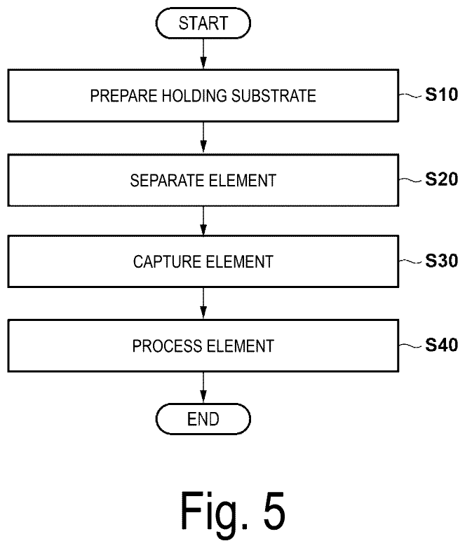

A method for manufacturing an electronic component or a semiconductor device according to one embodiment of the present invention includes a step of separating an element from a holding substrate and a step of capturing the element in a pressure sensitive adhesive sheet. Thus, an electronic component or a semiconductor device can be manufactured by further subjecting the element captured in the pressure sensitive adhesive sheet to processing. A method for manufacturing such an electronic component or a semiconductor device will be described below in detail with reference to the flowchart of FIG. 5.

### S10: Prepare Holding Substrate

In step S10, a holding substrate to which an element is attached is prepared. The type of the element is not particularly limited. For example, the element may be a semiconductor chip such as an LED chip, a semiconductor chip having a protective film, a semiconductor chip having a die attach film (DAF), or the like. Furthermore, the element may be a micro light-emitting diode, a mini light-emitting diode, a power device, micro electro mechanical systems (MEMS), or a controller chip, or may be a constituent component of these devices. The element may be a singulated product such as a wafer, a panel, and a substrate. The element may include a circuit surface on which an integrated circuit including circuit elements such as transistors, resistors, and capacitors is formed. Furthermore, the element is not necessarily limited to a singulated product, and may be various types of wafers, various types of substrates, or the like, which are not singulated.

The size of the element is not particularly limited. For example, the size of the element may be 100 μm² or greater, 500 μm² or greater, or 1000 μm² or greater. On the other hand, the size of the element may be 100 mm2 or less, 25 mm² or less, or 1 mm² or less. When an element having a small size is used, a laser lift-off method described later is suitable for attaching the element, because it is easy to selectively separate the small element.

Examples of the wafer include semiconductor wafers such as a silicon wafer, a silicon carbide (SiC) wafer, and a compound semiconductor wafer (for example, a gallium phosphide (GaP) wafer, a gallium arsenide (GaAs) wafer, an indium phosphide (InP) wafer, and a gallium nitride (GaN) wafer). The size of the wafer is not particularly limited, but may be 8 inches (200 mm in diameter) or greater and is preferably 12 inches (300 mm in diameter) or greater. A shape of the wafer is not limited to a circular shape and may be, for example, an angular shape such as a square and a rectangle.

Examples of the panel include a fan-out type semiconductor package (for example, a fan-out wafer-level package (FOWLP) or a fan-out panel-level package (FOPLP)). That is, the object to be processed may be a semiconductor package before singulation or after singulation in a fan-out type semiconductor package manufacturing technique. The size of the panel is not particularly limited, and the panel may be an angular substrate of about 300 to 700 mm, for example.

Examples of the substrate include a glass substrate, a sapphire substrate, and a compound semiconductor substrate.

The type of the holding substrate is not particularly limited. For example, the holding substrate may be a pressure sensitive adhesive sheet or a tray. The pressure sensitive adhesive sheet may include a pressure sensitive adhesive layer, and the pressure sensitive adhesive layer may be provided on a base material. In this case, the holding substrate can hold the element in the pressure sensitive adhesive layer. The base material may be a resin film or a rigid base material.

A method for preparing such a holding substrate that holds the element is not particularly limited. For example, the semiconductor wafer can be attached to the holding substrate, and further, the semiconductor wafer can be diced. Thus, an element can be obtained by dicing the semiconductor wear, so that it is possible to obtain a holding substrate to which the element is attached.

In another method, an element obtained by dicing a semiconductor wafer is transferred to a holding substrate, and thus, it is possible to obtain a holding substrate to which the element is attached. For example, after the semiconductor wafer held on the wafer substrate is diced, the obtained element can be brought into close contact with the pressure sensitive adhesive layer of the holding substrate. Subsequently, by applying an external stimulus such as laser light, the adhesiveness between the wafer substrate and the element can be lowered. Through such a process, the element can be transferred from the wafer substrate to the holding substrate.

As described later, in one embodiment, the element is separated from the holding substrate by irradiation with laser light (laser lift-off method). When such a method is used, it is preferable that the pressure sensitive adhesive layer of the holding substrate contain a laser light absorber. Examples of the laser light absorber include one or more types selected from pigments and dyes.

### S20: Separate Element

In step S20, the element attached to the holding substrate is separated from the holding substrate by an external stimulus. The type of the external stimulus is not particularly limited, and examples thereof include application of energy, cooling, drawing of the holding substrate, and physical stimulation (for example, pressing of a rear surface of the holding substrate by using a pin or the like). With one or more of these external stimuli, the bonding force between the holding substrate and the element can be reduced and the element can be separated from the holding substrate.

In the present embodiment, the element can be captured in step S30 such that the relative arrangement of the plurality of elements on the holding substrate is different from the relative arrangement of the plurality of elements on the pressure sensitive adhesive sheet. Thus, in step S20, it is preferable to selectively separate some of the plurality of elements attached to the holding substrate. Accordingly, in step S20, it is possible to selectively apply an external stimulus to some of the plurality of elements attached to the holding substrate or to an attachment site of the elements on the holding substrate.

Examples of a method for applying energy include local heating, light irradiation, and heat ray irradiation. Examples of the light irradiation method include infrared irradiation, visible light irradiation, and laser light irradiation. Preferably, laser light irradiation is used as the external stimulus, that is, the element is separated from the holding substrate by a laser lift-off method. In this case, laser light is emitted toward an attachment site of a specific element on the holding substrate. For example, the laser light may be emitted from a side opposite to the side of the holding substrate where the element is located. At a contact portion between the specific element and the holding substrate, gas is generated. For example, when the laser light is absorbed by the pressure sensitive adhesive layer, gas is generated by sublimation of at least a part of the pressure sensitive adhesive layer. When at least a part of the pressure sensitive adhesive layer sublimates as described above, the adhesion area between the specific element and the pressure sensitive adhesive layer decreases, and thus, the adhesive strength between the specific element and the holding substrate is reduced. Furthermore, the pressure of the generated gas also reduces the adhesive strength between the specific element and the holding substrate. As a result, the specific element is separated from the holding substrate.

The irradiation conditions of the laser light are not particularly limited. In order to selectively and efficiently separate a part of the elements, the frequency of the laser light is preferably from 10,000 Hz to 100,000 Hz. Further, the beam diameter of the laser light is preferably 10 μm or greater, and more preferably 20 μm or greater. On the other hand, the beam diameter is preferably 100 μm or less, and more preferably 40 μm or less. The output of the laser light is preferably from 0.1 W to 10 W. The scanning speed of the laser light is preferably from 50 mm/second to 2000 mm/second.

### S30: Capture Element

In step S30, the element separated from the holding substrate is captured by the pressure sensitive adhesive sheet. Specifically, the element is removed relative to the holding substrate. Further, the element relatively approaches the pressure sensitive adhesive sheet. When the element and the pressure sensitive adhesive layer of the pressure sensitive adhesive sheet contact each other, the element is captured by the pressure sensitive adhesive sheet.

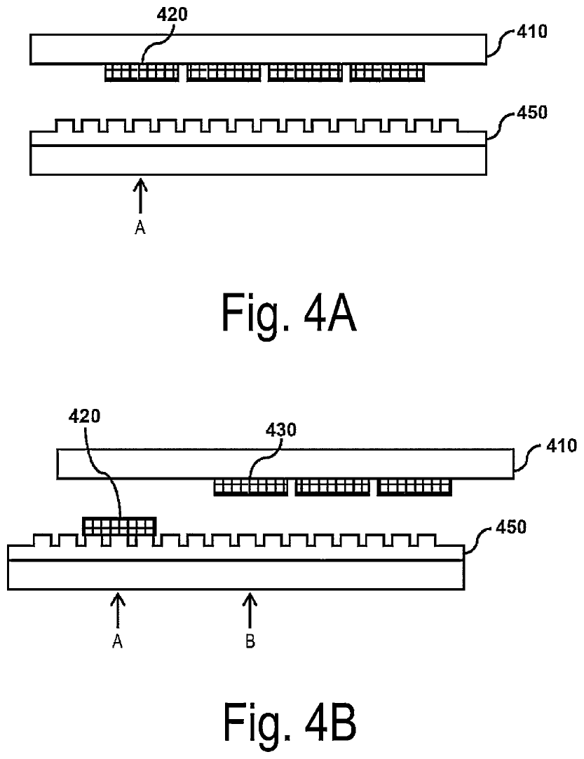

As illustrated in FIG. 4A, by positioning a position A on a pressure sensitive adhesive sheet 450 so as to face an element 420 adhering to a holding substrate 410, the separated element 420 is captured at the position A on the pressure sensitive adhesive sheet 450. Furthermore, as illustrated in FIG. 4B, by positioning a position B on the pressure sensitive adhesive sheet 450 so as to face an element 430 adhering to the holding substrate 410, the separated element 430 is captured at the position B on the pressure sensitive adhesive sheet 450. Thus, it is possible to separate and capture the element, while changing the relative position between the holding substrate and the pressure sensitive adhesive sheet in a plane direction. Therefore, the elements can be positioned such that the relative arrangement of the plurality of elements on the holding substrate is different from the relative arrangement of the plurality of elements on the pressure sensitive adhesive sheet. However, as described above, when a pressure sensitive adhesive sheet having a flat surface is used, the element 420 may be captured at a position deviated from the position A in the example of FIG. 4A due to pressure generated between the element and the pressure sensitive adhesive sheet. When the surface of the pressure sensitive adhesive layer has an unevenness, the pressure generated between the element and the pressure sensitive adhesive layer is relaxed, so that it is easier to capture the element at a desired position of the pressure sensitive adhesive sheet.

In one embodiment, the holding substrate and the pressure sensitive adhesive sheet are stationary, and the element separated from the holding substrate moves to the pressure sensitive adhesive sheet. For example, when a laser lift-off method is used, the element can move toward the pressure sensitive adhesive sheet by the pressure of the gas generated by the irradiation with laser light. However, the element does not necessarily need to move. For example, the holding substrate may move away from the element. Alternatively, the pressure sensitive adhesive sheet may move so as to approach the element.

### S40: Process Element

In step S40, an electronic component or a semiconductor device is manufactured by using the element captured in the pressure sensitive adhesive sheet. For example, the element captured in the pressure sensitive adhesive sheet may be transferred to a wiring substrate. The wiring substrate may include a wiring line connected to the element. In this case, the position of each element on the wiring substrate is determined in advance. Therefore, in step S30, a plurality of elements can be captured by the pressure sensitive adhesive sheet so that the plurality of elements are arranged to coincide with the relative arrangement of the plurality of elements on the wiring substrate. Subsequently, the wiring substrate is bonded to the surfaces of the plurality of elements on a side opposite to the pressure sensitive adhesive sheet. Furthermore, the pressure sensitive adhesive sheet is peeled off from the plurality of elements. According to such a procedure, a plurality of elements can be attached to the wiring substrate. Thus, an electronic component or a semiconductor device including an element (for example, a semiconductor element) can be manufactured.

In another example, the pressure sensitive adhesive sheet in which the element is captured may be attached to a substrate or another element. Furthermore, a process such as wiring by an appropriate method may be used to manufacture an electronic component or a semiconductor device including an element (for example, a semiconductor element) on a substrate therein, and an electronic component or a semiconductor device including laminated elements therein. When the pressure sensitive adhesive sheet is used in such an application, the pressure sensitive adhesive sheet preferably includes, in addition to the base material and the pressure sensitive adhesive layer, an additional pressure sensitive adhesive layer provided on the surface of the base material on a side opposite to the pressure sensitive adhesive layer.

### EXAMPLES

In Examples and Comparative Examples, the following compounds were used.
Styrene-based block copolymer (A): styrene-based block copolymer SBS containing 1,2-vinyl group (content of styrene block: 20 mass %, content of butadiene block: 80 mass %, content of diblock body: 13 mass %, content of constitutional unit having 1,2-vinyl group in a side chain among all constitutional units constituting butadiene block: 42 mol %, number average molecular weight (Mn): 160,000, mass average molecular weight (Mw): 180,000, Tg: −40° C.)
Liquid butadiene resin having a reactive functional group (B): liquid butadiene rubber (Mw: 5500, Tg: −49° C.)
Photopolymerization initiator (C): acylphosphine oxide photopolymerization initiator (manufactured by IGM Resins, Omnirad 819)

### Example 1

100 parts by mass of the styrene-based block copolymer (A), 3 parts by mass of the photopolymerization initiator (C), and 3 parts by mass of an antioxidant (Irganox 1010/Irgafos 168= 1/1, both manufactured by BASF) were dissolved in toluene to prepare an adhesive composition. This adhesive composition was coated onto a release treatment surface of a release sheet (trade name: SP-PET381130, manufactured by LINTEC Corporation). The obtained coating was dried at 100° C. during two minutes to form a pressure sensitive adhesive layer having a thickness of 25 μm. An easily adhesive surface of a PET film base material (manufactured by Toyobo Co., Ltd., thickness of 50 μm, trade name: PET50A4160) was attached to the pressure sensitive adhesive layer to prepare a pressure sensitive adhesive sheet.

After the release sheet was peeled off, the pressure sensitive adhesive layer of the pressure sensitive adhesive sheet was attached to a replica mold formed with a recess shape in advance. The obtained product was subjected to vacuum lamination at 100° C. and 0.5 MPa during 300 seconds. Next, the obtained product was irradiated with ultraviolet rays at an illuminance of 200 mW/cm² and a light amount of 800 mJ/cm² by using a UV irradiator (manufactured by Heraeus Group) to prepare a pressure sensitive adhesive sheet having an uneven shape on a surface thereof. The storage modulus of the pressure sensitive adhesive layer at 23° C. was 1.0 MPa, and the adhesion was 0.13 N/25 mm.

The uneven shape of the pressure sensitive adhesive layer of the pressure sensitive adhesive sheet was a shape in which tapered pillars are arranged in a lattice pattern, similarly to FIG. 2A. Each of the pillars functions as an adhesive island. In Example 1, a plurality of pressure sensitive adhesive sheets having convex portions with different pitches were prepared. The pitch (P) between the pillars in each pressure sensitive adhesive sheet was 20 μm, 30 μm, or 40 μm. The height (H) of each pillar illustrated in FIG. 3A was 7 μm, the diameter (T) of the top portion was 8 μm, and the diameter (B) of the base portion was 16 μm. In Example 1, other Examples, and Comparative Examples, a replica mold having a surface shape complementary to such an uneven shape was used to form the uneven shape on the pressure sensitive adhesive sheet.

The ratio of the area of the bonding portion between the pressure sensitive adhesive layer and the element to be captured (that is, the area of the top surfaces of the convex portions) relative to the area of the pressure sensitive adhesive sheet is respectively about 12.6%, 5.9%, and 3.1% at a pitch of 20 μm, 30 μm, and 40 μm.

### Example 2

100 parts by mass of the styrene-based block copolymer (A), 33.5 parts by mass of the liquid butadiene resin having a reactive functional group (B), 3 parts by mass of the photopolymerization initiator (C), and 3 parts by mass of an antioxidant (Irganox 1010/Irgafos 168= 1/1, both manufactured by BASF) were dissolved in toluene to prepare an adhesive composition. The adhesive composition was used to prepare a pressure sensitive adhesive sheet, similarly to Example 1. The storage modulus of the pressure sensitive adhesive layer at 23° C. was 0.36 MPa, and the adhesion was 0.36 N/25 mm.

### Example 3

100 parts by mass of the styrene-based block copolymer (A), 100 parts by mass of the liquid butadiene resin having a reactive functional group (B), 3 parts by mass of the photopolymerization initiator (C), and 3 parts by mass of an antioxidant (Irganox 1010/Irgafos 168= 1/1, both manufactured by BASF) were dissolved in toluene to prepare an adhesive composition. The adhesive composition was used to prepare a pressure sensitive adhesive sheet, similarly to Example 1. The storage modulus of the pressure sensitive adhesive layer at 23° C. was 0.16 MPa, and the adhesion was 0.52 N/25 mm.

### Comparative Example

A pressure sensitive adhesive sheet was prepared similarly to Example 1, except that the pressure sensitive adhesive layer was not attached to a replica mold and not subjected to vacuum lamination. In the Comparative Example, no unevenness was formed in the pressure sensitive adhesive layer.

### Method for Measuring Elastic Modulus of Pressure Sensitive Adhesive Layer

The storage modulus of the pressure sensitive adhesive layer according to each Example was measured as described below. That is, a pressure sensitive adhesive layer having a thickness of 25 μm was formed from the adhesive composition used in each Example, and the pressure sensitive adhesive layer was laminated so as to obtain a thickness of 3 mm. The laminated body was irradiated with ultraviolet rays at an illuminance of 200 mW/cm² and a light amount of 800 mJ/cm² by using a UV irradiator (manufactured by Heraeus Group) to cross-link the pressure sensitive adhesive layer. The obtained pressure sensitive adhesive layer was punched into a cylindrical shape having a diameter of 8 mm. A storage modulus G′ of the sample was measured by a torsional shear method under conditions including 23° C. and 1 Hz using a viscoelasticity measuring device (manufactured by Rheometrics, device name “DYNAMIC ANALYZER RDAII”).

### Method for Measuring Adhesion of Pressure Sensitive Adhesive Layer

The adhesion of the pressure sensitive adhesive layer according to each Example was measured as described below. That is, before being attached to the replica mold, the pressure sensitive adhesive sheet (release sheet/pressure sensitive adhesive layer/PET film base material) manufactured according to each Example was irradiated with ultraviolet rays at an illuminance of 200 mW/cm² and a light amount of 800 mJ/cm² by using a UV irradiator (manufactured by Heraeus Group) to cross-link the pressure sensitive adhesive layer. Subsequently, the release sheet was peeled off, and the exposed pressure sensitive adhesive layer of the pressure sensitive adhesive sheet was attached to a Si wafer. A roller having a weight of 2 kg was reciprocated on the obtained product once to obtain a measurement sample. The measurement sample was left under conditions including 23° C. and 50% RH during 24 hours. Subsequently, the adhesion (N/25 mm) was measured by using a tensile tester (TENSILON, manufactured by Orientec Co., Ltd.) under conditions including a peeling rate of 300 mm/min and a peeling angle of 180°. In the measurement, conditions other than those described herein were in conformity with JIS Z0237: 2009.

### Evaluation of Performance

The pressure sensitive adhesive sheets prepared in Examples 1 to 3 and the Comparative Example were used in a test for capturing an element. In the test, a semiconductor chip (270 μm×350 μmt) attached to a laser lift-off (LLO) tape (manufactured by LINTEC Corporation, former UV type, product name: Ab-24, film thickness of pressure sensitive adhesive: 30 μm) was prepared. Furthermore, a pressure sensitive adhesive sheet was attached onto a quartz glass plate via a general-purpose adhesive. A pressure sensitive adhesive tape was arranged at an interval from the LLO tape so that the pressure sensitive adhesive sheet was parallel to the LLO tape and the pressure sensitive adhesive surface faced the side of the LLO tape. The distance (gap) between the surface of the semiconductor chip and the pressure sensitive adhesive layer was 50 μm, 100 μm, 250 μm, or 500 μm. Subsequently, a laser beam having an output of 700 mJ/cm2 and an irradiation size of 270 μm×270 μm was emitted from the rear surface of the LLO tape.

When irradiated with laser light, the semiconductor chip separated from the LLO tape, moved toward the pressure sensitive adhesive sheet, and contacted the pressure sensitive adhesive layer of the pressure sensitive adhesive sheet. Subsequently, it was confirmed whether or not the semiconductor chip adhered to the pressure sensitive adhesive sheet. Furthermore, it was confirmed whether or not the position of the semiconductor chip remained the same with respect to the LLO tape in a plan view (that is, whether or not the position of the semiconductor chip deviated when the semiconductor chip was captured by the pressure sensitive adhesive sheet). When the semiconductor chip adhering to the pressure sensitive adhesive sheet and the position of the semiconductor chip did not deviate, it was determined that the semiconductor chip was successfully captured. The results are presented below in the table. In the table, A/B indicates that the semiconductor chip was successfully captured A times in B repetitions of the test.

TABLE 1

| | | | | | | | | | | Comparative |
|---|---|---|---|---|---|---|---|---|---|---|
| | Example 1 | | | Example 2 | | | Example 3 | | | Example |
| | Elastic modulus: | | | Elastic modulus: | | | Elastic modulus: | | | Elastic modulus: |
| | 1.0 MPa | | | 0.5 MPa | | | 0.1 MPa | | | 1.0 MPa |
| Pitch | 20 | 30 | 40 | 20 | 30 | 40 | 20 | 30 | 40 | None |
| (μm) | | | | | | | | | | |
| Gap 50 | 5/5 | 5/5 | 1/4 | 5/5 | 5/5 | 0/5 | 5/5 | 5/5 | 5/5 | 0/5 |
| μm | | | | | | | | | | |
| Gap 100 | 5/5 | 5/5 | 2/4 | 5/5 | 5/5 | 4/5 | 5/5 | 5/5 | 5/5 | 0/5 |
| μm | | | | | | | | | | |
| Gap 250 | 5/5 | 5/5 | 3/4 | 5/5 | 5/5 | 3/5 | 5/5 | 5/5 | 5/5 | 0/5 |
| μm | | | | | | | | | | |
| Gap 500 | 1/5 | 2/5 | 0/5 | 5/5 | 4/5 | 0/5 | 5/5 | 5/5 | 5/5 | 0/5 |
| μm | | | | | | | | | | |

In a case in which the unevenness was not provided in the pressure sensitive adhesive layer, as in the Comparative Example, the element was not successfully captured. On the other hand, by providing the unevenness in the pressure sensitive adhesive layer, the element was likely to be captured successfully. When the pitch of the convex portions was smaller, the element was more likely to be captured successfully. The reason for this is considered to be that, as the pitch is smaller, the contact area between the pressure sensitive adhesive layer and the element increases. Therefore, the adhesive strength between the pressure sensitive adhesive sheet and the element increases. It was confirmed that the element was successfully captured, even when the pitch was further narrowed and the contact area between the pressure sensitive adhesive layer and the element was about 30%.

Furthermore, when the gap was increased, the element was less likely to be captured successfully. However, by lowering the elastic modulus of the pressure sensitive adhesive layer, as in Example 3, it was possible to successfully capture the element, even when the gap was large. In Example 3, the element was successfully captured, even when the pitch of the convex portions was large. As described above, it was confirmed that a low elastic modulus of the pressure sensitive adhesive layer was advantageous when the element was captured by the pressure sensitive adhesive sheet having an uneven surface.

The invention is not limited to the above-described embodiments, and various modifications and changes can be made within the spirit of the invention.

What is claimed is:

1. A pressure sensitive adhesive sheet for capturing an element detached from a holding substrate, the pressure sensitive adhesive sheet comprising:
a pressure sensitive adhesive layer having a surface having an unevenness.

2. The pressure sensitive adhesive sheet according to claim 1, wherein the pressure sensitive adhesive layer has a storage modulus of 0.001 MPa or greater and 100 MPa or less.

3. The pressure sensitive adhesive sheet according to claim 1, wherein the pressure sensitive adhesive layer includes, on the surface, a plurality of convex portions separated from each other via a concave portion.

4. The pressure sensitive adhesive sheet according to claim 1, wherein the pressure sensitive adhesive layer includes a plurality of convex portions separated from each other with a boundary defined by a concave portion, and a pitch between the plurality of convex portions is 1 μm or greater and 100 μm or less.

5. The pressure sensitive adhesive sheet according to claim 1, wherein the pressure sensitive adhesive layer includes a plurality of convex portions separated from each other with a boundary defined by a concave portion, and an area of each of the plurality of convex portions is 10 μm² or greater and 2000μm² or less.

6. The pressure sensitive adhesive sheet according to claim 1, wherein the pressure sensitive adhesive layer includes a convex portion with a boundary defined by a concave portion, and
a ratio of an area occupied by the convex portion relative to an area of the pressure sensitive adhesive layer is 1% or greater and 95% or less.

7. The pressure sensitive adhesive sheet according to claim 1, wherein the pressure sensitive adhesive layer is configured such that a ratio of an adhesion area between the pressure sensitive adhesive layer and one element relative to an area of the one element is 1% or greater and 95% or less.

8. The pressure sensitive adhesive sheet according to claim 1, wherein the pressure sensitive adhesive sheet is separated from the holding substrate by an external stimulus, and the element detached from the holding substrate is captured in the pressure sensitive adhesive layer.

9. A method for manufacturing an electronic component or a semiconductor device, the method comprising:
separating an element adhering to a holding substrate from the holding substrate by an external stimulus; and
capturing the element separated from the holding substrate to be detached from the holding substrate, in the pressure sensitive adhesive sheet according to claim 1.
